(19) United States
(12) Patent Application Publication
(10) Pub. No.: US 2025/0390615 A1
(43) Pub. Date: Dec. 25, 2025

(54) PREFORM COVER GLASS SHAPE PREDICTION DEVICE AND METHOD

(71) Applicant: SAMSUNG DISPLAY CO., LTD., Yongin-si (KR)

(72) Inventor: Beom Gyu CHOI, Yongin-si (KR)

(21) Appl. No.: 19/175,180

(22) Filed: Apr. 10, 2025

(30) Foreign Application Priority Data
Jun. 25, 2024 (KR) 10-2024-0083170
Jul. 18, 2024 (KR) 10-2024-0095324

(51) Int. Cl. G06F 30/10; C03B 23/03; G02F 1/1333; G06F 30/27; H05K 5/03; H10H 29/85; H10K 59/80

(52) U.S. Cl. CPC G06F 30/10; C03B 23/0307; G06F 30/27; H05K 5/03; C03B 2215/41; G02F 1/133331; H10H 29/8506; H10K 59/872

(57) ABSTRACT

A preform cover glass shape prediction device for predicting a shape of a preform cover glass, the device includes a preform cover glass prediction model generator trained to obtain input data representing a training curved cover glass and a training preform cover glass, to generate cover glass characteristic data based on the input data, and to generate a predicted design specification of a target preform cover glass based on the cover glass characteristic data, and a preform cover glass shape predictor configured to generate a predicted design specification for a preform cover glass corresponding to a target curved cover glass based on the cover glass characteristic data and characteristic data of the target curved cover glass.

### CROSS-REFERENCE TO RELATED APPLICATION

This U.S. nonprovisional patent application claims priority under 35 U.S.C. § 119 to Korean Patent Application Nos. 10-2024-0083170 filed on Jun. 25, 2024 and 10-2024-0095324 filed on Jul. 18, 2024, in the Korean Intellectual Property Office, the disclosures of which are incorporated by reference herein in their entirety.

### BACKGROUND

### 1. Field

Embodiments of the present disclosure relate to a preform cover glass shape prediction device and method, and particularly to a preform cover glass shape prediction device and method for forming a curved cover glass.

### 2. Discussion of the Related Art

As information technology advances, display devices, which serve as the interface between users and information, are gaining increased significance. Accordingly, the use of display devices, such as liquid crystal display devices and organic light emitting display devices, is increasing. In some aspects, a cover glass is disposed in front of the display device to protect the display panel of the display device.

With the development of portable devices having curved surfaces, the demand for cover glasses including curved surfaces is growing. In general, curved glass products applied to various electronic products are manufactured through a thermoforming process to a preform cover glass (e.g., an original form of glass) cut to match the target curved specifications of the glass. Glass thermoforming refers to the process of raising the glass to the softening point and then shaping the tempered glass into the target shape specified by, for example, the glass specification.

In some cases, the shape, dimension, and overall configuration of the preform cover glass affect the shape of the final cover glass after the thermoforming process. Accordingly, if the preliminary cover glass shape cannot be accurately predicted to achieve the target final cover glass shape, the manufacturing cost may increase due to an increase in the product development period and an increase in design of experiments (DOE). Therefore, a method for predicting the shape of a preform cover glass for forming a curved cover glass is needed to efficiently and accurately manufacture the curved cover glass on a display device.

### SUMMARY

Embodiments of the present disclosure provide a preform cover glass shape prediction device and method for accurately predicting the preliminary cover glass shape for generating a curved cover glass shape.

A preform cover glass shape prediction device for predicting a shape of a preform cover glass, the device includes a preform cover glass prediction model generator trained to obtain input data representing a training curved cover glass and a training preform cover glass, to generate cover glass characteristic data based on the input data, and to generate a predicted design specification of a target preform cover glass based on the cover glass characteristic data, and a preform cover glass shape predictor configured to generate a predicted design specification for a preform cover glass corresponding to a target curved cover glass based on the cover glass characteristic data and characteristic data of the target curved cover glass.

A method for predicting a preform cover glass shape, the method includes obtaining input data including characteristic data of a curved corner part of a training curved cover glass and characteristic data of a flat corner part of a training preform cover glass, generating cover glass characteristic data based on the input data, training a machine learning model to generate a predicted design specification of a target preform cover glass based on the cover glass characteristic data, obtaining characteristic data of a curved corner part of a target curved cover glass, and generating, using the trained machine learning model, a predicted design specification for a preform cover glass corresponding to the target curved cover glass based on the cover glass characteristic data.

A computer device including at least one memory, and at least one processor configured to execute computer-readable instructions stored in the at least one memory, wherein the at least one processor is configured to perform operations including obtaining input data including characteristic data of a curved corner part of a training curved cover glass and characteristic data of a flat corner part of a training preform cover glass, generating cover glass characteristic data based on the input data, training a machine learning model to generate a predicted design specification of a target preform cover glass based on the cover glass characteristic data, obtaining characteristic data of a curved corner part of a target curved cover glass, and generating, using the trained machine learning model, a predicted design specification for a preform cover glass corresponding to the target curved cover glass based on the cover glass characteristic data.

An electronic device including a processor, a memory having stored application programs for execution by the processor, a preform cover glass shape prediction model including a preform cover glass prediction model generator trained to obtain input data representing a training curved cover glass and a training preform cover glass, to generate cover glass characteristic data based on the input data, and to generate a predicted design specification of a target preform cover glass based on the cover glass characteristic data, and a preform cover glass shape predictor configured to generate a predicted design specification for a preform cover glass corresponding to a target curved cover glass based on the cover glass characteristic data and characteristic data of the target curved cover glass, and a user interface configured to sense user input via touch or cursor select of an icon presented on a display panel, wherein the processor is caused to execute one or more of the stored application programs upon receipt of the user input.

### BRIEF DESCRIPTION OF THE DRAWINGS

FIG. 1 is a diagram schematically illustrating a curved cover glass for a display device according to embodiments of the present disclosure.

FIG. 2 is a flowchart illustrating a method of forming a curved cover glass according to an embodiment of the present disclosure.

FIG. 3 is a top view of the preform cover glass according to embodiments of the present disclosure.

FIG. 4 is a diagram of a side view illustrating an example of pressing a preform cover glass with a mold according to embodiments of the present disclosure.

FIG. 5 is a diagram showing a preform cover glass shape prediction device according to an embodiment of the present disclosure.

FIG. 6 is a diagram showing a detailed configuration of the preform cover glass prediction model generator of FIG. 5.

FIG. 7 is a diagram illustrating data corresponding to a flat corner part of the preform cover glass according to embodiments of the present disclosure.

FIG. 8A and FIG. 8B are diagrams illustrating data quantification related to surface and cross-sectional curves of the curved corner part of the cover glass, respectively.

FIG. 9 is a diagram illustrating data quantification results according to an embodiment of the present disclosure.

FIG. 10 is a diagram showing simulation results of synthetic data according to an embodiment of the present disclosure.

FIG. 11 is a diagram showing simulation results of filtered synthetic data according to an embodiment of the present disclosure.

FIG. 12 is an example diagram illustrating a neural network model according to an embodiment of the present disclosure.

FIG. 13 is a diagram illustrating an example of a computer device according to an embodiment.

FIG. 14 is a diagram illustrating an electronic device according to an embodiment of the present disclosure.

### DETAILED DESCRIPTION

Embodiments of the present disclosure provide a preform cover glass shape prediction device and method using a machine learning model to accurately predict the shape and design specifications of preform cover glass for generating a curved cover glass. The system (or the preform cover glass shape prediction device) includes a preform cover prediction model generator is trained with characteristic data from a curved corner part of a training curved cover glass and characteristic data of a flat corner part of a training preform cover glass. In one aspect, the preform cover prediction model generator includes a machine learning model. The preform cover prediction model generator preprocesses and input data to generate cover glass characteristic data using Gaussian curvature and transformations. Additionally, the preform cover prediction model generator augments training data to improve model accuracy and reduce reliance on costly real-world evaluations.

In some aspects, the system includes a preform cover glass prediction model generator trained to generate a prediction model that can accurately generate a design specification of a target preform cover glass for molding a target curved cover glass. The preform cover glass prediction model generator is trained to obtain cover glass characteristic data from input data related to the curved corner parts of a training curved cover glass and preform glass characteristic data from the flat corner parts of the corresponding training preform cover glass. Additionally, the model generates additional synthetic training input data based on the cover glass characteristic data, where the additional synthetic training input data have a same distribution as the distribution of the cover glass characteristic data. By further training the preform cover glass prediction model generator using the combined input and output dataset, the generator is able to accurately and efficiently generate the specifications (e.g., the size, shape, and overall configuration) of a target preform cover glass based on an input data related to a target curved cover glass.

In some embodiments, the preform cover glass prediction model generator further generates transformed target data based on the original target data from the input data. By doing so, the system linearizes the non-linear input data, allowing the machine learning model to efficiently learn the relationship among the dataset. Accordingly, the linearization reduces computational cost by enabling the machine learning model to process data more efficiently, resulting in faster and more accurate predictions. Therefore, production speed in manufacturing environments can be increased.

According to embodiments, the accuracy of predicting the corner shape of the preform cover glass may be improved by quantifying the design variables of the curved cover glass and generating new characteristic data through the quantified values.

In addition, according to embodiments, the cost of securing data for machine learning is reduced and machine learning performance is improved through data synthesis and filtering of new characteristic data for predicting the corner shape of the preform cover glass.

Hereinafter, with reference to the attached drawings, various embodiments of the present disclosure are described in detail so that those skilled in the art can easily implement the embodiments of the present disclosure. The invention may be implemented in many different forms and is not limited to the embodiments described herein.

In order to clearly explain the present disclosure, parts that are not relevant to the description may be omitted, and identical or similar components are given the same reference numerals throughout the specification.

In addition, the size and thickness of each component shown in the drawings are merely used as examples for the convenience of explanation, so the present disclosure is not necessarily limited to that which is shown.

Additionally, when a part of a layer, membrane, region, or plate is described to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part may be substantially the same as being disposed above or below the reference part, and does not necessarily indicate being disposed “above” or “on” it in the direction opposite to gravity.

In addition, throughout the specification, when a part is described to “include” a certain component, the part may further include other components rather than excluding other components, unless specifically stated to the contrary.

In addition, terms such as “part” and “module” used in the specification refer to a part that processes at least one function or operation, which may be implemented through hardware, software, circuit, or a combination thereof.

In this specification, “transmission” or “provision” may include not only direct transmission or provision, but also indirect transmission or provision through another device or using a circuitous route.

It will be understood that, although the terms “first,” “second,” etc. may be used herein to describe various elements, these elements should not be limited by these terms. These terms are only used to distinguish one element from another element. For example, a first element discussed below could be termed a second element without departing from the teachings and spirit of the present disclosure. Similarly, the second element could also be termed the first element.

In this specification, expressions described as singular may be interpreted as singular or plural, unless explicit expressions such as “one” or “single” are used. Hereinafter, various embodiments of the present disclosure are described in detail with reference to the drawings.

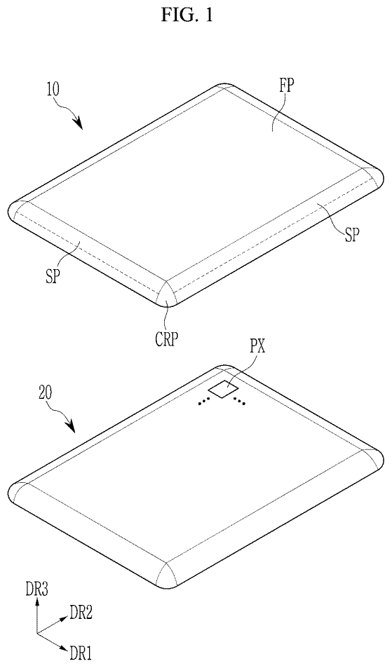

FIG. 1 is a diagram schematically illustrating a curved cover glass for a display device according to embodiments of the present disclosure. Referring to FIG. 1, a cover glass 10 may be disposed on a display panel 20 to protect a display panel 20. The cover glass 10 may be manufactured using a tempered glass substrate that has undergone a strengthening treatment. As a result, the cover glass 10 may have a shape with curved edges similar to the curved edges of the display panel 20.

According to an embodiment, the cover glass 10 may include a flat part FP with a flat surface, side parts SP each adjacent to the edges of the flat part FP, and curved corner parts CRP each connecting the adjacent side parts SP. In some cases, the curved corner parts CRP are disposed adjacent to the corners of the flat part FP of the cover glass 10. Each of the side parts SP may be bent around a virtual bending axis extending parallel to the edge of the flat part FP. The bending axis may extend in a first direction DR1 or a second direction DR2. Accordingly, each of the side parts SP may have a curved surface that is convex outward.

A thickness T of the cover glass 10 may be substantially uniform. For example, the thickness T of the flat part FP, the thickness T of a curved corner part CRP, and the thickness T of the side part SP of the cover glass 10 may be substantially the same. However, the present disclosure is not limited to this, and the thickness T of the cover glass 10 may vary based on the regions of the cover glass 10.

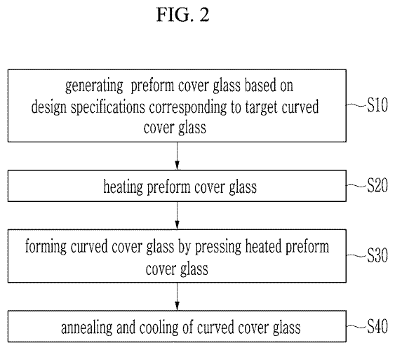

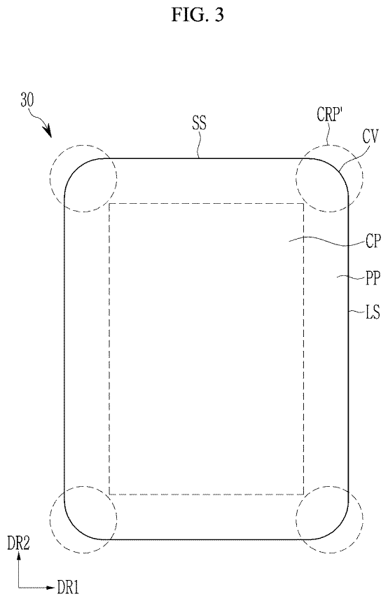

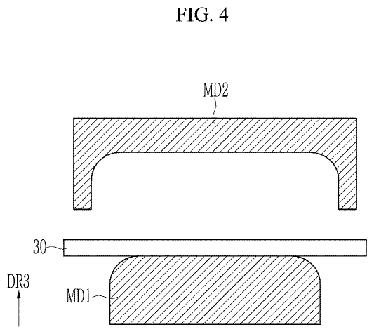

FIG. 2 is a flowchart illustrating a method of forming a curved cover glass according to an embodiment of the present disclosure. FIG. 3 is a plan view of a preform cover glass according to embodiments of the present disclosure. FIG. 4 is a diagram of a side view illustrating an example of pressing the preform cover glass with a mold according to embodiments of the present disclosure.

Referring to FIGS. 1 to 4, the cover glass forming method according to an embodiment may include step S10 of generating a preform cover glass based on a design specification corresponding to a target curved cover glass, step S20 of heating the preform cover glass, step S30 of forming a curved cover glass by pressing the heated preform cover glass, and step S40 of annealing and cooling the curved cover glass.

First, a glass substrate, a material used as the curved cover glass, is processed based on a design specification corresponding to the target curved cover glass to form a preform cover glass (preliminary mold, 30) for molding the curved cover glass 10 (S10). For example, the preform cover glass 30 has a form of a flat glass before the thermoforming process. The design specifications for processing the preform cover glass 30 may be provided by a preform cover glass shape predictor, as described later. In some cases, the design specification may include the dimension of the shape, dimension, and overall configuration of the preform cover glass.

The preform cover glass 30 may include a center part CP and a peripheral part PP. The peripheral part PP of the preform cover glass 30 may be adjacent to the edges of the center part CP. For example, the peripheral part PP of the preform cover glass 30 may surround the center part CP of the preform cover glass 30. The center part CP of the preform cover glass 30 is formed as the flat part FP of the cover glass 10 as shown in FIG. 1 through the molding method, and the peripheral part PP of the preform cover glass 30 may be formed into the side part SP and the curved corner part CRP of the cover glass 10 through the molding method.

The planar shape of the peripheral part PP of the preform cover glass 30 may include a short side SS extending in a first direction DR1, a long side LS extending in a second direction DR2 perpendicular to the first direction DR1, and a curved line CV connecting the end of the short side SS to the end of the long side LS. For example, the peripheral part PP of the preform cover glass 30 may include a flat corner part CRP′ adjacent to the vertex of the center part CP, and the flat corner part CRP′ may include the curved line CL. For example, the preform cover glass 30 may include two short sides SS, two long sides LS, and four curved lines CV. However, the present disclosure is not limited to the example shown, and the number of short sides SS, long sides LS, and curved lines CV of the preform cover glass 30 may vary based on the shape of the display panel.

Referring to FIG. 2, the preform cover glass 30 may be heated locally (S20). For example, the peripheral part PP of the preform cover glass 30 may be heated locally, and the center part CP may not be heated S20. For example, because the heat applied to the center part CP is relatively small, heat damage applied to the center part CP may be minimized. In some cases, the center part CP of the cover glass 30 may retain the flat shape during the pressing process, and heating the center part CP might not be required.

Then, the preform cover glass 30 may be pressed while the peripheral part PP of the preform cover glass 30 is heated (S30). For example, the step S30 of pressing the preform cover glass 30 may be performed at least partially simultaneously with the step S20 of heating the preform cover glass 30.

Referring to FIG. 4, after placing the preform cover glass 30 on a first mold MD1, the preform cover glass 30 may be pressed with a second mold MD2. As the preform cover glass 30 is pressed with the second mold MD2, the edge of the preform cover glass 30 may be bent along the shape of the first mold MD1. Here, the first mold MD1 may have a rectangular cross-sectional shape with rounded corners. Additionally, the second mold MD2 may have a cross-sectional shape that engages the first mold MD1. For example, according to an embodiment, the preform cover glass 30 may be pressed with the second mold MD2 at a gradually increasing pressure, and then the preform cover glass 30 may be pressed at a constant pressure. In some cases, the center of the preform cover glass 30 may be substantially aligned with the center of the first mold MD1 or the second mold MD2. In some cases, after the pressing process, the edges of the preform cover glass 30 may be substantially parallel with the lower surface of the first mold MD1.

Subsequently, the curved cover glass 10 formed by pressing the preform cover glass 30 may be annealed and cooled (S40). Through the thermoforming method as described, the curved cover glass 10 shown in FIG. 1 may be formed from the preform cover glass 30.

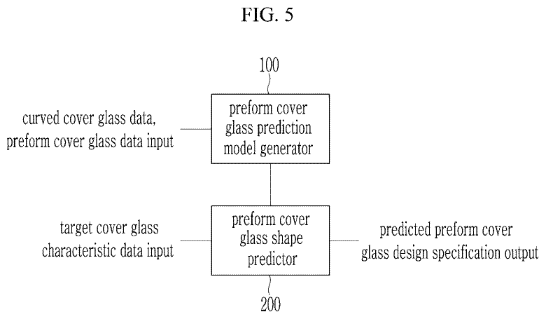

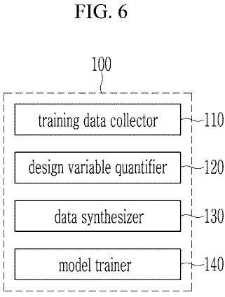

The following describes an apparatus and method for predicting the shape of a preform cover glass according to an embodiment. FIG. 5 is a diagram illustrating a preform cover glass shape prediction device according to an embodiment of the present disclosure. FIG. 6 is a diagram illustrating a detailed configuration of the prediction model generator of FIG. 5.

Referring to FIG. 5, the preform cover glass shape prediction device according to an embodiment includes a preform cover glass prediction model generator 100 and a preform cover glass shape predictor 200. The preform cover glass prediction model generator 100 obtains input data including numerical data related to the completed curved cover glass and numerical data related to the preform cover glass corresponding to the completed curved cover glass. In some aspects, the preform cover glass prediction model generator 100 extracts characteristic data based on the input data. For example, the characteristic data includes cover glass characteristic data related to the surface and cross-sectional curves of the curved corner part of the completed curved cover glass, and preform glass characteristic data related to the flat corner part of the preform cover glass. In addition, the preform cover glass prediction model generator 100 includes a machine learning model trained based on the extracted cover glass characteristic data and the preform cover glass characteristic data to predict the design specifications of the target preform cover glass for molding the target curved cover glass.

The preform cover glass shape predictor 200 receives characteristic data of the target cover glass. For example, the characteristic data of the target cover glass includes information about the surface and cross-sectional curves of the curved corner part of the target curved surface cover glass. In some embodiments, the preform cover glass shape predictor 200 generates the design specifications of the predicted preform cover glass based on the target cover glass characteristic data.

In some embodiments, the preform cover glass prediction model generator 100 includes a training data collector 110, a design variable quantifier 120, a data synthesizer 130, and a model trainer 140 (as shown in FIG. 6).

The training data collector 110 obtains training data for training the machine learning model of the preform cover glass prediction model generator 100. In some cases, the training data collector 110 may receive a data set containing a plurality of data. According to an embodiment, the training data collector 110 collects numerical data of the cover glass 10 that have no visible defects and meet dimensional specifications based on actual evaluations, along with corresponding numerical data of preform cover glass. For example, the training data collector 110 collects numerical data corresponding to the curved corner of the completed curved cover glass as training input data for the machine learning model, and collects numerical data corresponding to the flat corner part of the preform cover glass corresponding to the completed curved cover glass as training output data for the machine learning model.

According to some embodiments, the training data collector 110 obtains the training data from a cover glass 10 and a preform cover glass. For example, the machine learning model is trained to obtain an input data representing the curved corners of the completed curved cover glass (e.g., the cover glass 10) and to generate an output data representing the flat corner part of the preform cover glass. In some cases, the output data includes a design specification output that indicates the, shape, dimension, or overall configuration of the preform cover glass.

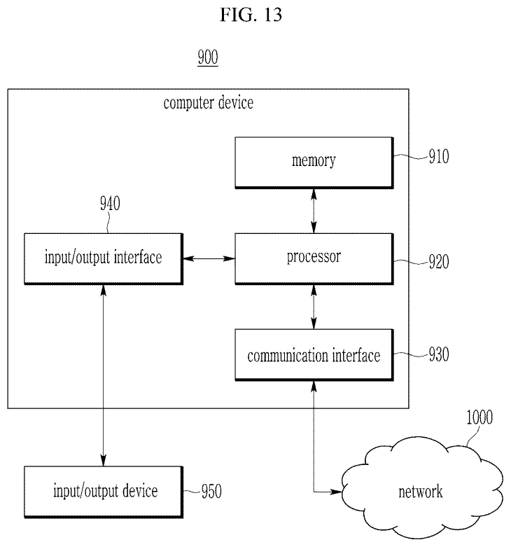

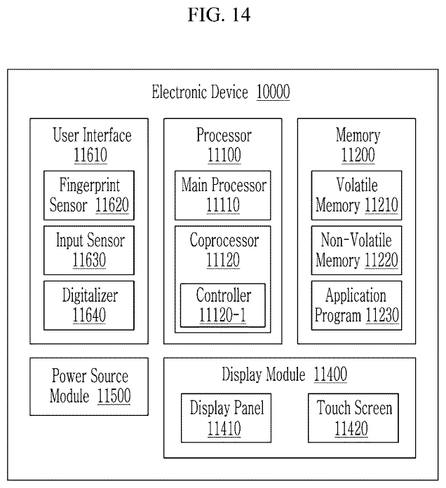

In some cases, a machine learning model is a computational algorithm, model, or system designed to recognize patterns, make predictions, or perform a specific task (for example, image processing) without being explicitly programmed. According to some aspects, the machine learning model is implemented as software stored in memory unit (e.g., the memory 910 in FIG. 13 or the memory 11200 in FIG. 14) and executable by processor unit (e.g., the processor 920 in FIG. 13 or the processor 11100 in FIG. 14), as firmware, as one or more hardware circuits, or as a combination thereof.

According to some embodiments of the present disclosure, the machine learning model includes an ANN, which is a hardware or a software component that includes a number of connected nodes (e.g., artificial neurons), which loosely correspond to the neurons in a human brain. Each connection, or edge, transmits a signal from one node to another (like the physical synapses in a brain). When a node receives a signal, the node processes the signal and then transmits the processed signal to other connected nodes. In some cases, the signals between nodes comprise real numbers, and the output of each node is computed by a function of the sum of its inputs. In some examples, nodes may determine the output using other mathematical algorithms (e.g., selecting the max from the inputs as the output) or any other suitable algorithm for activating the node. Each node and edge is associated with one or more node weights that determine how the signal is processed and transmitted.

During the training process, the one or more node weights are adjusted to increase the accuracy of the result (e.g., by minimizing a loss function that corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on the corresponding inputs. The initial layer is known as the input layer and the last layer is known as the output layer. In some cases, signals traverse certain layers multiple times.

In one aspect, machine learning model includes machine learning parameters. Machine learning parameters, also known as model parameters or weights, are variables that provide behaviors and characteristics of the machine learning model. Machine learning parameters can be learned or estimated from training data and are used to make predictions or perform tasks based on learned patterns and relationships in the data.

Machine learning parameters are adjusted during a training process to minimize a loss function or maximize a performance metric. The goal of the training process is to find optimal values for the parameters that allow the machine learning model to make accurate predictions or perform well on the given task.

For example, during the training process, an algorithm adjusts machine learning parameters to minimize an error or loss between predicted outputs and actual targets according to optimization techniques like gradient descent, stochastic gradient descent, or other optimization algorithms. Once the machine learning parameters are learned from the training data, the machine learning parameters are used to make predictions on new, unseen data.

According to some embodiments, the machine learning model includes a computer-implemented recurrent neural network (RNN). An RNN is a class of ANN in which connections between nodes form a directed graph along an ordered (e.g., a temporal) sequence. This enables an RNN to model temporally dynamic behavior such as predicting what element should come next in a sequence. Thus, an RNN is suitable for tasks that involve ordered sequences such as text recognition (where words are ordered in a sentence). In some cases, an RNN includes one or more finite impulse recurrent networks (characterized by nodes forming a directed acyclic graph), one or more infinite impulse recurrent networks (characterized by nodes forming a directed cyclic graph), or a combination thereof.

According to some embodiments, the machine learning model includes a transformer (or a transformer model, or a transformer network), where the transformer is a type of neural network model used for natural language processing tasks. A transformer network transforms one sequence into another sequence using an encoder and a decoder. The encoder and decoder include modules that can be stacked on top of each other multiple times. The modules comprise multi-head attention and feed-forward layers. The inputs and outputs (target sentences) are first embedded into an n-dimensional space. Positional encoding of the different words (e.g., give each word/part in a sequence a relative position since the sequence depends on the order of its elements) is added to the embedded representation (n-dimensional vector) of each word.

In some examples, a transformer network includes an attention mechanism, where the attention looks at an input sequence and decides at each step which other parts of the sequence are important. The attention mechanism involves a query, keys, and values denoted by Q, K, and V, respectively. Q is a matrix that contains the query (vector representation of one word in the sequence), K are the keys (vector representations of the words in the sequence) and V are the values, which are again the vector representations of the words in the sequence. For the encoder and decoder, multi-head attention modules, V consists of the same word sequence as Q. However, for the attention module that takes into account the encoder and the decoder sequences, V is different from the sequence represented by Q. In some cases, values in V are multiplied and summed with some attention-weights.

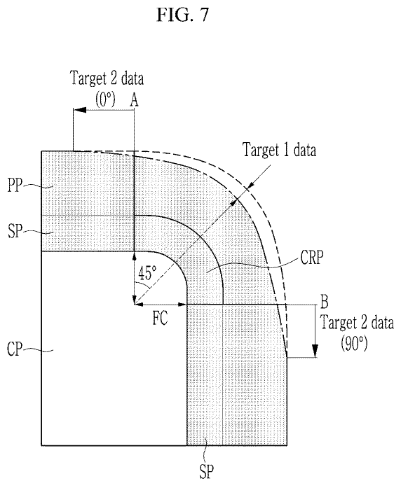

FIG. 7 is a diagram illustrating data corresponding to the flat corner part of the preform cover glass according to embodiments of the present disclosure. According to an embodiment, as illustrated in FIG. 7, data for Target 1 and Target 2, which are regions near the flat corner part of the preform cover glass 30, are collected to be used as output training data (target data) for the machine learning model.

In FIG. 7, the data related to Target 1 (hereinafter referred to as “Target 1 data”) represents the change in the cross-section extended at an arbitrary angle (e.g., 45 degrees in FIG. 7) from the point corresponding to the vertex of the center part CP of the preform cover glass 30. The data related to Target 2 (hereinafter referred to as “Target 2 data”) represents the change in the cross-section extended at 0 degrees or 90 degrees from the point corresponding to the vertex of the center part CP of the preform cover glass 30. In FIG. 7, the change amount of a cross-section extended at a 45-degree angle is used as Target 1 data, but the present disclosure is not limited hereto. For example, the change amount of a cross-section extended at a different angle (for example, 22.5 degrees) may be used as the Target 1 data.

In FIG. 7, the gray part corresponds to the peripheral part PP of the preform cover glass 30 shown in FIG. 3, and the white part corresponds to the center part CP of the preform cover glass. Referring to FIG. 7, the side part of the completed cover glass is bent in one direction, so the curved region of the flat corner part of the target preform cover glass related to Target 1 is represented by a dotted line, which is a curve calculated by simple dimensional calculation by unfolding the bent parts SP and the curved corner part CRP of the completed cover glass.

However, since the flat corner part expands due to thermoforming, the one-dot chain line inside the dotted line was set as the design curve area (indicated in gray). In some cases, the starting point of the flat corner part (i.e., the bending starting point) ideally begins at the point corresponding to the vertex of the preform cover glass, but in light of the fact that the corner part expands due to thermoforming, the starting point was set closer to the flat part than the point corresponding to the vertex of the preform cover glass. For example, points A and B represents the vertex of the preform cover glass at 0 degrees and 90 degrees, respectively. However, due to the expanding of the preform cover glass during the thermoforming process, the starting point (or the point that where the glass begins to expand) of one corner part begins at the left side of point A. Similarly, the starting part of the other corner part begins at a region lower than point B.

Accordingly, in an embodiment, the difference between the ideal curve (dotted line) and the design curve (dash-dot line) corresponding to the cross-sectional part extending at an arbitrary angle (for example, 45 degrees) from the point corresponding to the vertex of the center part (CP) of the preform cover glass was set as Target 1 data. Additionally, the degree of change at the starting point of the edge (bending starting point) of the preform cover glass was set as Target 2 data. In addition, the length of the flat part before bending begins at the point corresponding to the vertex of the center part CP of the preform cover glass is represented as a flat corner length FC. The Target 1 data and Target 2 data may be used to extract preform glass characteristic data used as training output data (target data) of a machine learning model, as described later.

Referring back to FIG. 6, the design variable quantifier 120 performs preprocessing on the design variables (data related to curved corner parts) of the cover glass 10 and the design variables (data related to flat curved parts) of the preform cover glass, quantifies the data for the design variables, and outputs original trained data.

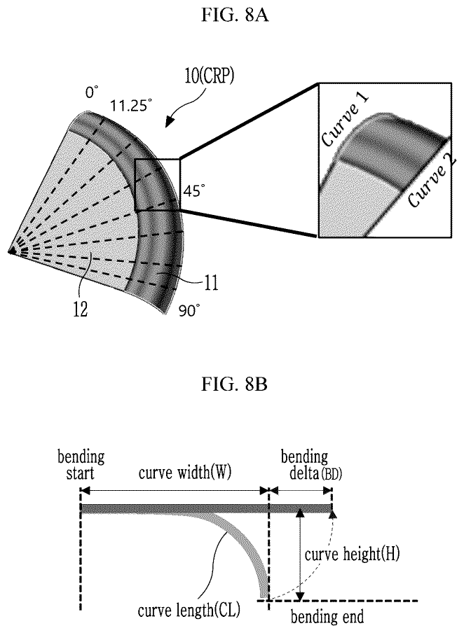

In an embodiment, the curved corner part of the cover glass 10 is divided into two elements—a surface and a cross-sectional curve—and data quantification is performed for the surface and the cross-sectional curve, respectively. FIG. 8A and FIG. 8B are diagrams illustrating data quantification related to the surface and cross-sectional curve of the curved corner part of the cover glass 10, respectively.

FIG. 8A is a diagram showing an example of the surface and cross-sectional curve of the curved corner part of the cover glass 10. In an embodiment, as shown in FIG. 8A, the surface of the corner part CRP of the cover glass 10 may be divided into N pieces (e.g., 8 pieces), and data quantification may be performed using Gaussian curvature for each of the divided surfaces (e.g., 8 divided surfaces). The Gaussian curvature of this division surface may be used as input training data for a machine learning model. The Gaussian curvature is quantifies the degree of curvature at a point on a curved surface and is computed as the product of the two principal curvatures at the point. Principal curvatures refer to the maximum and minimum curvatures among the curvatures of intersection curves formed between the curved surface and planes containing a normal vector at a point on the curved surface.

In FIG. 8A, the curved corner part CRP of the cover glass 10 includes a flat corner region 12 and a curved surface region 11. The curved surface region 11 may have a different degree of bending (i.e., radius of curvature) based on the distance from the flat corner region 12. According to an embodiment, although the degree of bending increases with distance from the flat corner region 12, even when there are differences in the degree of bending, the actual influence of the bending angle on the Gaussian curvature is minimal.

In an embodiment, characteristic data related to the cross-sectional curve is additionally quantified and used in addition to the Gaussian curvature. In an embodiment, the characteristic data of the curves Curve 1 and Curve 2 corresponding to both boundaries of the divided surface in FIG. 8A are additionally used to quantify data related to the curved corner parts. Hereinafter, the cross-sectional curve used as characteristic data is referred to as a characteristic curve. In FIG. 8A, cross-sectional curves at both boundaries of the surface divided by characteristic curves were used, so eight divided surfaces and nine characteristic curves were used, but the present disclosure is not limited to this. For example, in FIG. 8A, cross-sectional curves at both boundaries of the surface divided by characteristic curves are used, but the present disclosure is not limited to this, and cross-sectional curves at arbitrary positions may be used as characteristic curves. In some embodiments, the characteristic data includes one characteristic curve and the Gaussian curvature. In some embodiments, the characteristic data includes three or more characteristic curves and the Gaussian curvature.

FIG. 8B is a diagram showing an example of the characteristic curves Curve 1 and Curve 2 of the divided surface shown in FIG. 8A. As shown in FIG. 8B, the characteristic curve of the curved corner part of the cover glass 10 is formed between a bending start and a bending end. Hereinafter, the distance between the normal plane (e.g., a plane substantially at the same level as the horizontal surface) at the bending start and the tangent plane (e.g., a plane substantially at the same level as the vertical surface) at the bending end is represented as a curve width W, and the distance between the tangent plane at the bending start and the normal plane at the bending end is represented as a curve height H.

In some cases, quantifying the data of the curved corner part of the cover glass 10 with the curve width, curve height, and curve length of the a given cross-sectional curve may be challenging. Accordingly, the difference values between the curve width, curve height, and curve length that make up the cross-sectional curve are additionally used to quantify the design variable data.

Referring to FIG. 8B, the difference between curve length and curve width is represented as bending delta. The bending delta represents the degree of bending of the curved corner part of the cover glass 10 by thermoforming, and the greater the degree of bending, the greater the bending delta. According to an embodiment, the bending delta BD may be obtained using Equation 1 below.

$$BD = CL - W \qquad ( Equation 1 )$$

For example, BD represents the bending delta, CL represents the curve length, and W represents the curve width.

In some embodiments, the difference between the sum of the curve width W and curve height H and the cross-sectional curve length L is represented as length delta, and data related to the curved corner part is further quantified using the length delta. For example, the length delta LD may be obtained using Equation 2 below.

$$LD = ( W + H ) - CL \qquad ( Equation 2 )$$

Further detail on a data quantification process using the additional characteristic data related to the cross-sectional curve is described.

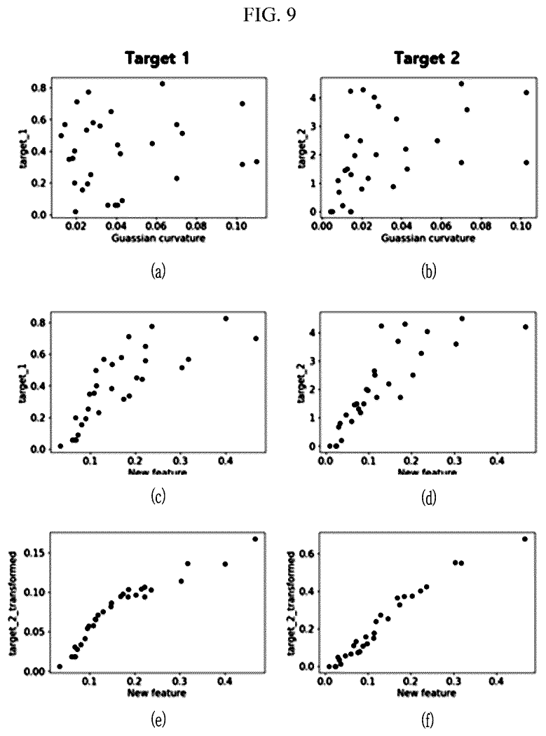

FIG. 9 is a diagram illustrating data quantification results according to an embodiment of the present disclosure. Graphs (a) and (b) of FIG. 9 are diagrams showing the Gaussian curvature on the curved surface of the cover glass corresponding to Target 1 data and Target 2 data of the preform cover glass, respectively. Here, Target 1 data represents the difference between the ideal curve and the design curve corresponding to a cross-section extending at an arbitrary angle (e.g., 45 degrees) from a point corresponding to the vertex of the center part CP of the preform cover glass. Target 2 data represents the degree of change in the corner starting point of the preform cover glass.

In graphs (a) and (b) of FIG. 9, the Y-axis represents Target 1 data and Target 2 data of the preform cover glass, respectively, and the X-axis represents the Gaussian curvature on the divided surface of the cover glass. As illustrated in graphs (a) and (b) of FIG. 9, there is minimal linear correlation between the Target 1 data and the Target 2 data of the preform cover glass and the Gaussian curvature on the divided surface of the cover glass.

Graph (c) of FIG. 9 is a diagram showing the relationship between Target 1 data of the preform cover glass and the transformed Gaussian curvature on the divided surface of the cover glass. Graph (d) of FIG. 9 is a diagram showing the relationship between Target 2 data of the preform cover glass and the transformed Gaussian curvature on the divided surface of the cover glass.

According to an embodiment, the transformed Gaussian curvature GC′ is a transformation of the Gaussian curvature on the divided surface by reflecting the change in the curve, and represents a new characteristic of the divided surface. The transformed Gaussian curvature GC′ may be obtained using Equation 3, which is the target transformation equation.

$${GC}^{′} = GC \times BD 1 \times BD 2 = GC \times ( CL 1 - W 1 ) \times ( CL 2 - W 2 ) \qquad ( Equation 3 )$$

Here, GC′ represents the transformed Gaussian curvature of the divided surface, GC represents the Gaussian curvature of the divided surface, BD1 and BD2 represent the bending deltas of the two characteristic curves of the divided surface, respectively, CL1 and CL2 represent the curve lengths of the two characteristic curves of the divided surface, respectively, and W1 and W2 represent the curve widths of the two characteristic curves, respectively.

Graphs (c) and (d) of FIG. 9 are graphs in which the Gaussian curvature of the divided surface on the X-axis in graphs (a) and (b) of FIG. 9 is replaced with the transformed Gaussian curvature obtained by Equation 3. For example, in graphs (c) and (d) of FIG. 9, the Y-axis represents Target 1 data and Target 2 data of the preform cover glass, respectively, and the X-axis represents the transformed Gaussian curvature on the divided surface of the cover glass. Comparing graphs (c) and (d) of FIG. 9 with graphs (a) and (b) of FIG. 9, it appears that the linearity between the Target 1 data/Target 2 data of the preform cover glass and the transformed Gaussian curvature on the divided surface of the cover glass has improved. By generating the transformed Gaussian curvature of the divided surface, the relationship between the target data (e.g., Target 1 data and Target 2 data) of the divided surface of the cover glass and the curvature (e.g., the Gaussian curvature) of the divided surface of the cover glass can be linearized.

Graphs (e) and (f) of FIG. 9 are diagrams showing the relationship between transformed Target 1 data, transformed Target 2 data, respectively, and transformed Gaussian curvature on the divided surface of the cover glass according to an embodiment. According to an embodiment, the transformed target data is transformed based on the bending delta and the length delta in the Target 1 data and Target 2 data. For example, transformed target data (e.g., the transformed Target 1 data and transformed Target 2 data) may be obtained using Equation 4, which includes a target transformation equation.

$${Target}_{1} = \frac{{BD}_{T 1}}{{BD}_{T 1} + {LD}_{T 1}} \qquad ( Equation 4 )$$

$${Target}_{2} = \frac{{BD}_{T 2}}{FC + {BD}_{T 2} + {LD}_{T 2}}$$

For example, Target1 and Target2 represent the transformed Target 1 data and Target 2 data, respectively. BDT1 and LDT1 represent the bending delta and length delta of the curved surface curve of the cover glass corresponding to Target 1, respectively. BDT2 and LDT2, FC represent the bending delta, the length delta, and the flat corner length of the curved surface curve of the cover glass corresponding to Target 2, respectively.

Graphs (e) and (f) of FIG. 9 are graphs in which Target 1 data and Target 2 data on the Y-axis in graphs (c) and (d) of FIG. 9 are replaced with the transformed Target 1 data and transformed Target 2 data obtained by Equation 4. For example, in graphs (e) and (f) of FIG. 9, the Y-axis represents transformed Target 1 data and transformed Target 2 data, respectively, and the X-axis represents the transformed Gaussian curvature on the divided surface of the cover glass. By generating the transformed target data (e.g., the transformed Target 1 data and transformed Target 2 data, the relationship between the target data (e.g., Target 1 data and Target 2 data) of the divided surface of the cover glass and the curvature (e.g., the transformed Gaussian curvature) of the divided surface of the cover glass can be linearized. Accordingly, the preform cover glass shape prediction device can efficiently process the input data and generate a predicted design specification of the preform cover glass.

According to an embodiment, the Gaussian curvature, transformed Gaussian curvature, curve length, curve width, curve height of each characteristic curve, and flat corner length at each divided surface of the cover glass may be used as cover glass characteristic data as training input data of a machine learning model. Additionally, the transformed Target 1 data and transformed Target 2 data are preform glass characteristic data and may be used as training output data (target data) of the machine learning model. For example, the Gaussian curvature, transformed Gaussian curvature, curve length, curve width, curve height of each characteristic curve, flat corner length, transformed Target 1 data, and transformed Target 2 data at each divided surface of the cover glass may be used as the original training data for the machine learning model.

Referring to FIG. 6, the data synthesizer 130 augments data for the machine learning model by synthesizing data with respect to the original training data, which are the data quantified by the design variable quantifier 120.

To obtain the training data for the machine learning model, actual evaluation on the dataset may be performed. However, this approach is expensive due to the high cost associated with the production and evaluation period of the cover glass. Accordingly, in an embodiment, a large amount of training data may be generated by synthesizing data using a synthetic data model.

According to an embodiment, synthetic data may be generated for original training data using the Synthetic Data Vault (SDV) library, and hyperparameter tuning may be performed on the synthetic data. According to an embodiment, a Bayesian optimization technique, a method for finding the optimal solution of an unknown objective function, may be used for hyperparameter tuning. For example, a Gaussian Copula function may be used as a surrogate model to estimate the objective function based on the data. In addition, for optimal hyperparameter tuning, simulations are performed using Gaussian distribution, beta distribution, gamma distribution, and Gaussian_KDE (Kernal Density Estimation) distribution as statistical distributions of the Gaussian Copula function.

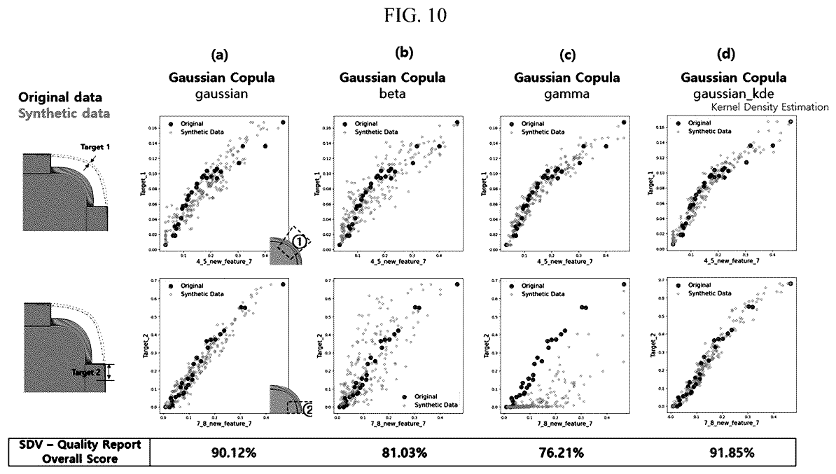

FIG. 10 is a diagram showing simulation results according to an embodiment of the present disclosure. For example, the diagram shows simulation results of hyperparameter tuning using a Gaussian distribution, beta distribution, gamma distribution, and Gaussian_KDE distribution after generating synthetic data using the SDV library according to an embodiment.

In FIG. 10, dark dots represent the original trained data shown in graphs (e) and (f) of FIG. 9, the top graph shows the relationship between transformed Target 1 data (Y-axis) versus transformed Gaussian curvature at divided surfaces of the cover glass (X-axis). Furthermore, the bottom graph shows transformed Target 2 data (Y-axis) versus transformed Gaussian curvature at divided surface (X-axis).

In FIG. 10, the light dots represent the results of hyperparameter tuning after performing data synthesis using the SDV library on the original trained data, where graphs (a), (b), (c), and (d) show the results of hyperparameter tuning using Gaussian distribution, beta distribution, gamma distribution, and Gaussian_KDE distribution of the Gaussian Copula function, respectively. By performing data augmentation using data synthesizer 130 of FIG. 6, the system can generate synthetic data having a distribution similar to the original training data using the Gaussian distribution and the Gaussian_KDE distribution.

According to an embodiment, the data synthesizer 130 may perform filtering on synthetic data and perform hyperparameter tuning on the filtered synthetic data to generate augmented training data that can be used to further train the machine learning model. Additionally, the data synthesizer 130 may generate training data for the machine learning model by performing augmentation on data that has undergone synthesis and hyperparameter tuning.

For example, the data synthesizer 130 may generate final training data for the machine learning model by filtering out points that do not satisfy Equation 3 and Equation 4, which are target transformation equations, from among the synthetic data indicated by light dots in FIG. 10.

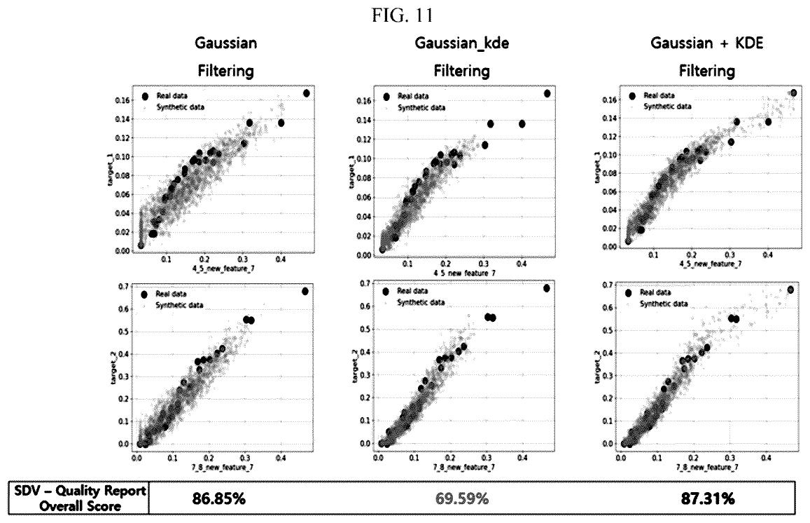

FIG. 11 is a diagram showing simulation results of filtered synthetic data according to an embodiment of the present disclosure. For example, the diagram shows simulation results of hyperparameter tuning using Gaussian distribution, Gaussian_KDE distribution, and Gaussian+KDE distribution after performing filtering on synthetic data generated from original trained data using the SDV library.

In FIG. 11, Gaussian+KDE distribution refers to a mixed use of Gaussian distribution and Gaussian_KDE distribution, and in an embodiment, Gaussian distribution was used for curve length, curve width, curve height of each characteristic curve, flat corner length, and Gaussian curvature at each divided surface, while Gaussian_KDE distribution was used for transformed Gaussian curvature, transformed Target 1 data, and Target 2 data. By generating the synthetic training dataset using either Gaussian distribution or Gaussian+KDE distribution, the synthetic training dataset may have a similar distribution as the distribution of the original training data. Accordingly, the amount of the training dataset can be increased using the synthetic dataset while retaining the same distribution.

Referring to FIG. 6, the model trainer 140 may train the machine learning model using the final training data generated from the data synthesizer 130. For example, the machine learning model may be include a neural network. For example, models such as deep neural network DNN and convolutional neural networks CNN may be used as machine learning models, but are not limited to these.

According to an embodiment, cover glass characteristic data including the Gaussian curvature, transformed Gaussian curvature, curve length, curve width, curve height of each characteristic curve, and flat corner length at each divided surface of the cover glass may be used as input data of the learning model, and preform glass characteristic data including transformed Target 1 data and transformed Target 2 data may be used as output data (target data) of the learning model.

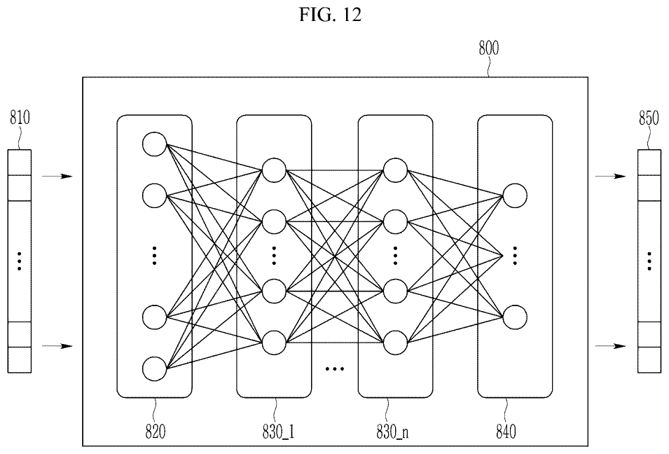

FIG. 12 is an example diagram illustrating a neural network model 800 according to an embodiment of the present disclosure. In some aspects, the machine learning model includes the neural network model 800. In some cases, the neural network model 800 may include a statistical learning algorithm implemented based on the structure of a biological neural network or a structure for executing the algorithm.

According to an embodiment, the neural network model 800 may include problem-solving capabilities in which nodes, which are artificial neurons formed into a network by the coupling of synapses as in a biological neural network, learn to iteratively adjust the weights of the corresponding synapses so that the error between the correct output and the inferred output in response to a given input is reduced. For example, the neural network model 800 may include a random probability model, a neural network model, etc. used in artificial intelligence learning methods such as machine learning and deep learning.

The neural network model 800 is implemented as a multilayer perceptron (MLP) including multiple layers of nodes and connections between the multiple layers. The neural network model 800 may be implemented using one of various artificial neural network model structures including MLP. As shown in FIG. 12, the neural network model 800 may include an input layer 820 configured to receive the input data including Gaussian curvature, transformed Gaussian curvature, curve length, curve width, curve height of each characteristic curve, and flat corner length at each divided surface of the cover glass. The output layer 840 is configured to output or generate transformed Target 1 data and transformed Target 2 data. In some aspects, n hidden layers (or intermediate neural network layers) 830_1 to 830_n (where n is a positive integer) is disposed between the input layer 820 and the output layer 840, which receive the output from the input layer 820, extract features, and transmit the extracted feature to the output layer 840. Here, the output layer 840 receives extracted feature from the hidden layers 830_1 to 830_n and generates an output (e.g., the transformed Target 1 data and transformed Target 2 data).

After training the machine learning model, the model trainer 140 may store the trained machine learning model. For example, the model trainer 140 may store the trained machine learning model in the memory of the preform cover glass shape predictor 200. Alternatively, the model trainer 140 may store the trained machine learning model in the memory of a server connected to the preform cover glass shape predictor 200 through a wired or wireless network.

The preform cover glass shape predictor 200 outputs predicted preform cover glass design specifications based on the characteristic data (cover glass characteristic data) of the surface and cross-sectional curves of curved corner parts at divided surfaces of the target cover glass and the output generated by the preform cover glass prediction model generator 100. For example, the characteristic data related to the surface of the curved corner part includes the Gaussian curvature of the divided surface and the transformed Gaussian curvature of the divided surface, while the characteristic data for the cross-sectional curve includes the curve length, curve width, curve height, length delta, and flat corner length of each characteristic curve.

FIG. 13 is a diagram illustrating an example of a computer device according to an embodiment. The preform cover glass prediction model generator 100 and the preform cover glass shape predictor 200 described in FIG. 5 may be implemented by the computer device 900 shown in FIG. 13.

As shown in FIG. 13, this computer device 900 may include a memory 910, a processor 920, a communication interface 930, and an input/output interface 940. Memory 910 is a computer-readable recording medium, which may include RAM (random access memory), ROM (read only memory), and permanent mass storage device such as, a disk drive. Additionally, an operating system and at least one program code may be stored in the memory 910. In some aspects, one or more software components may be stored in the memory 910 from a computer-readable recording medium separate from the memory 910. Such separate computer-readable recording media may include computer-readable recording media such as hard disks, flash memory, optical disks, and external hard drives. Additionally, one or more software components may be loaded into the memory 910 through the communication interface 930.

The processor 920 may be configured to process instructions of computer programs by performing basic arithmetic, logic, and input/output operations. Commands may be provided to the processor 920 by the memory 910 or the communication interface 930. Processor 920 is an intelligent hardware device, (e.g., a general-purpose processing component, a digital signal processor (DSP), a central processing unit (CPU), a graphics processing unit (GPU), a microcontroller, an application-specific integrated circuit (ASIC), a field programmable gate array (FPGA), a programmable logic device, a discrete gate or transistor logic component, a discrete hardware component, or a combination thereof. In some cases, processor 920 is configured to operate a memory array using a memory controller. In other cases, a memory controller is integrated into processor 920. In some cases, processor 920 is configured to execute computer-readable instructions stored in a memory to perform various functions. In some embodiments, processor 920 includes special-purpose components for modem processing, baseband processing, digital signal processing, or transmission processing.

The communication interface 930 may provide a function for the computer device 900 to communicate with other devices through the network 1000. communication interface 930 operates at a boundary between communicating entities (such as computer device 900, one or more user devices, a cloud, and one or more databases) and can record and process communications. In some cases, communication interface 930 is provided to enable a processing system coupled to a transceiver (e.g., a transmitter and/or a receiver). In some examples, the transceiver is configured to transmit (or send) and receive signals for a communications device via an antenna. In some cases, a bus is used in communication interface 930.

The input/output interface 940 may interface with an input/output device 950. For example, input devices may include devices such as a microphone, keyboard, or mouse, and output devices may include devices such as displays and speakers.

FIG. 14 is a diagram illustrating an electronic device according to an embodiment of the present invention. Processor 11100 is an example of, or includes aspects of, the corresponding element described with reference to FIG. 13. Memory 11200 is an example of, or includes aspects of, the corresponding element described with reference to FIG. 13.

Referring to FIG. 14, the electronic device 10000 according to one embodiment of the present invention may output various information (e.g., images, text, music, or the predicted preform cover glass design specification) through a display module 11400. When a processor 11100 executes an application stored in a memory 11200, the display module 11400 may provide application information to a user through a display panel 11410.

In some embodiments, the electronic device 10000 may be configured as a smartphone, camera, smart TV, monitor, smartwatch, tablet, automotive display, or AR/VR headset. For example, the electronic device 10000 may be a smartphone including a touch-sensitive display area DA for interaction and a non-display area NDA including sensors and circuits for enhanced functionality. For example, the electronic device 10000 may be a television or monitor including a large display area DA for high-resolution video playback and a non-display area NDA incorporating driving circuits or connectivity modules for external inputs. For example, the electronic device 10000 may be a smartwatch including a display area DA optimized for compact and high-clarity visuals and a non-display area NDA integrating biometric sensors for health monitoring. In some cases, the electronic device 10000 be an AR/VR headset.

In some embodiments, memory 11200 may store information such as software codes for operating an application program 11230. The application program 11230 may include a software designed to execute specific tasks or provide functionality to a user. The application program 11230 may operate under the control of the processor 11100 and utilizes data stored in the memory 11200 to deliver a wide range of features, such as productivity tools, multimedia streaming and playback, file or mail deliveries or communication services. The application program 11230 interacts seamlessly with the user interface 11610 or touch screen 11420, allowing a user to launch, navigate, and utilize the program through user inputs such as touch, tap, gesture, or voice interaction. According to some embodiments, software codes for the preform cover glass shape prediction device may be stored in the application program 11230. In some embodiments, the preform cover glass shape prediction device may be included in the electronic device 10000.

Upon user selection of an application via touch screen 11420 or user interface 11610, the processor 11100 may execute the application program 11230 corresponding to the selected application retrieved from the memory 11200 to perform functionalities of the application. For example, when a user selects a camera application by tapping the icon (or a camera application icon) presented on the display panel 11410, the processor 11100 activates a camera module. The processor 11100 may transmit image data corresponding to a captured image acquired through the camera module to the display module 11400. The display module 11400 may display an image corresponding to the captured image through the display panel 11410.

As another example, when a user wishes to make a phone call, the user taps the telephone icon displayed on the display module 11400, the processor 11100 may execute a phone application program stored in the memory 11200. A telephone keypad may be presented on the display panel 11410 for the user to enter a phone number to call.

As another example, the display module 11400 may be integrated into an electronic device 10000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 11100 may include a main processor 11110 and an auxiliary or coprocessor 11120. The main processor 11110 may include a central processing unit (CPU). The main processor 11110 may further include one or more of a graphics processing unit (GPU), a communication processor (CP), and an image signal processor (ISP).

The coprocessor 11120 may include a controller 11120-1. The controller 11120-1 may include an interface conversion circuit and a timing control circuit. The controller 11120-1 may receive an image signal from the main processor 11110, convert the data format of the image signal to match the interface specifications with the display module 11400, and output image data. The controller 11120-1 may output various control signals to drive the display module 11400. For example, the controller 11120-1 may drive the display module 11400 to display the icon on the display screen suitable for selection by a user to cause execution of an application program 11230.

The memory 11200 may store one or more application programs 11230 and various data used by at least one component (for example, the processor 11100 or the user interface 11610) of the electronic device 10000 and input data or output data for commands related thereto. For example, a camera application program, a GPS application program, an augmented reality and virtual reality application program, and other application programs that can be executed by the processor 11100 upon selection of corresponding icons presented on the display screen (or display panel 11410) via the touch screen 11420 or user interface 11610 by the user. In addition, various setting data corresponding to user settings may be stored in the memory 11200. The memory 11200 may include volatile memory 11210 and non-volatile memory 11220.

The display module 11400 may output visual information (images or the design specification of the predicted preform cover glass) to the user. The display module 11400 may include the display panel 11410, a gate driver, the source driver, a voltage generation circuit, and a touch screen 11420. The display module 11400 may further include a window, a chassis, and a bracket to protect the display panel 11410.

The user interface 11610 serves as the interaction medium between a user and the electronic device 10000. The user interface 11610 may detect an input by a part (e.g., finger) of a user's body or an input by a pen or a mouse, and generate an electric signal or data value corresponding to the input. The user interface 11610 includes the fingerprint sensor 11620, the input sensor 11630, and a digitizer 11640.

The fingerprint sensor 11620 may sense a fingerprint for biometric recognition of the user and may also measure one or more biological signals such as blood pressure, moisture, or body mass.

The input sensor 11630 may sense user interactions including touch, tap, gesture, motion, spoken command, and eye movement. The input sensor 11630 includes optical sensors for image capture, eye tracking, or motion and gesture detection. Optical sensors may be infrared or semiconductor photodetectors. The input sensor 11630 includes audio and acoustic sensors, which may be MEMS microphones for voice recognition or sound-based interaction. The audio and acoustic sensors can be installed as part of the user interface 11610 or embedded in the display panel 11410.

The digitizer 11640 may generate a data value corresponding to coordinate information of input by a pen or a mouse to control movement of an onscreen cursor. The digitizer 11640 may generate the amount of change in electromagnetic due to the input as the data value. The digitizer may detect an input by a passive pen or transmit and receive data with an active pen or a remote.

At least one of the fingerprint sensor 11620, the input sensor 11630, or the digitizer 11640 may be implemented as a sensor layer formed on the top layer of the display panel 11410 through a continuous process with a process of forming elements (for example, the light emitting element, the transistor, and the like) included in the display panel 11410.

In addition, the user interface 11610 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 11420 includes touch sensors embedded in semiconductor layers of the display panel 11410 to sense pressure applied to the top layer (screen) of the display panel 11410. The touch sensors can be a capacitive or a resistive type. The touch screen 11420 may serve as the primary interface for the user to select and navigate applications, control, and interact with the electronic device 10000.

The display panel 11410 (or display) may include a liquid crystal display panel, an organic light emitting display panel, or an inorganic light emitting display panel, and the type of the display panel 11410 is not particularly limited. The display panel 11410 may be of a rigid type or a flexible type that can be rolled or folded. The display module 11400 may further include a supporter, bracket, heat dissipation member, and the like that support the display panel 11410.

The power source module 11500 may supply power to the components of the electronic device 10000. The power source module 11500 may include a battery that charges the power source voltage. The battery may include a non-rechargeable primary battery or a rechargeable secondary battery or fuel cell. The power source module 11500 may include a power management integrated circuit (PMIC). The PMIC may supply optimized power source to each of the components described above including the display module 11400

The embodiments described above may be implemented in the form of computer programs that may be executed through various components on a computer, and such computer programs may be recorded on computer-readable media. For example, the media may include magnetic media such as hard disks, floppy disks, and magnetic tapes, optical recording media such as CD-ROMs and DVDs, magneto-optical media such as floptical disks, and hardware devices specifically configured to store and execute program instructions, such as ROM, RAM, and flash memory.

In the absence of explicit ordering of the steps comprising the method according to one embodiment, the steps may be performed in any suitable order. The present disclosure is not necessarily limited by the order of description of the above steps. The use of any examples or exemplary terms (e.g., etc.) in the present disclosure is merely for illustrating the present disclosure in detail and is not intended to limit the scope of the present disclosure. Additionally, those skilled in the art will recognize that various modifications, combinations and changes may be made within the scope of the patent claims or their equivalents.

Although embodiments of the present disclosure have been described in detail above, the scope of the present disclosure is not limited to these descriptions, and various modifications and improvements made by those skilled in the art to which the present disclosure pertains are also included within the scope of the present disclosure.

What is claimed is:

1. A preform cover glass shape prediction device for predicting a shape of a preform cover glass, comprising:
a preform cover glass prediction model generator trained to obtain input data representing a training curved cover glass and a training preform cover glass, to generate cover glass characteristic data based on the input data, and to generate a predicted design specification of a target preform cover glass based on the cover glass characteristic data; and
a preform cover glass shape predictor configured to generate a predicted design specification for a preform cover glass corresponding to a target curved cover glass based on the cover glass characteristic data and characteristic data of the target curved cover glass.

2. The preform cover glass shape prediction device of claim 1, wherein the preform cover glass prediction model generator further comprises:
a training data collector configured to obtain training input data corresponding to a curved corner part of the training curved cover glass and training output data corresponding to a flat corner part of the training preform cover glass corresponding to the training curved cover glass;
a design variable quantifier configured to generate transformed curvature data based on the training input data and the training output data, wherein the transformed curvature data include the characteristic data of the training curved cover glass and the characteristic data of the training preform cover glass;
a data synthesizer configured to generate augmented training data based on the training input data and the training output data and the transformed curvature data; and
a model trainer, using the augmented training data, trained to generate the predicted design specification of the target preform cover glass.

3. The preform cover glass shape prediction device of claim 2, wherein:
the curved corner part of the training curved cover glass is segmented into a plurality of surfaces, wherein each of the plurality of surfaces includes one or more characteristic curves, and
the transformed curvature data includes a Gaussian curvature, a transformed Gaussian curvature, a curve length, a curve width, a curve height of the one or more characteristic curves, and a flat corner length for each of the plurality of surfaces.

4. The preform cover glass shape prediction device of claim 3, wherein:
the design variable quantifier is configured to generate the characteristic data of the training preform cover glass of the training preform cover glass based on a first target data and a second target data.

5. The preform cover glass shape prediction device of claim 3, wherein:
the transformed curvature data is generated based on a first characteristic curve and second characteristic curve of a surface of the curved corner part of the training curved cover glass.

6. The preform cover glass shape prediction device of claim 5, wherein:
the design variable quantifier is configured to generate a transformed first target data and a transformed second target data based on the transformed curvature data.

7. The preform cover glass shape prediction device of claim 2, wherein:
the data synthesizer is configured to generate synthetic training data and filter the synthetic training data, wherein the augmented training data includes the filtered synthetic training data.

8. The preform cover glass shape prediction device of claim 7, wherein:
the data synthesizer is configured to remove a portion of the synthetic training data based on a target transformation function.

9. The preform cover glass shape prediction device of claim 7, wherein:
the synthetic training data is generated using a Synthetic Data Vault (SDV) library.

10. A method for predicting a preform cover glass shape, the method comprising:
obtaining input data including characteristic data of a curved corner part of a training curved cover glass and characteristic data of a flat corner part of a training preform cover glass;
generating cover glass characteristic data based on the input data;
training a machine learning model to generate a predicted design specification of a target preform cover glass based on the cover glass characteristic data;
obtaining characteristic data of a curved corner part of a target curved cover glass; and
generating, using the trained machine learning model, a predicted design specification for a preform cover glass corresponding to the target curved cover glass based on the cover glass characteristic data.

11. The method of claim 10, wherein obtaining the input data comprises:
obtaining training input data corresponding to the curved corner part of the training curved cover glass and training output data corresponding to the flat corner part of the training preform cover glass corresponding to the training curved cover glass;
generating transformed curvature data based on the training input data and the training output data, wherein the transformed curvature data include the characteristic data of the training curved cover glass and the characteristic data of the training preform cover glass;
generating augmented training data based on the training input data and the training output data and the transformed curvature data; and
generating the predicted design specification of a target preform cover glass.

12. The method of claim 11, wherein:
the curved corner part of the training curved cover glass is segmented into a plurality of surfaces, wherein each of the plurality of surfaces includes one or more characteristic curves, and
the transformed curvature data includes a Gaussian curvature, a transformed Gaussian curvature, a curve length of the one or more characteristic curves, a curve width, a curve height, and a flat corner length for each of the plurality of surfaces.

13. The method of claim 12, further comprises:
generating preform glass characteristic data of the training preform cover glass based on a first target data and a second target data.

14. The method of claim 13, further comprising:
generating the transformed curvature data based on a first characteristic curve and second characteristic curve of a surface of the curved corner part of the training curved cover glass.

15. The method of claim 14, further comprising:
generating a transformed first target data and a transformed second target data based on the transformed curvature data.

16. The method of claim 15, wherein:
generating synthetic training data; and
filtering the synthetic training data, wherein the augmented training data includes the filtered synthetic training data.

17. The method of claim 16, further comprising:
remove a portion of the synthetic training data based on a target transformation function.

18. A computer device comprising:
at least one memory; and
at least one processor configured to execute computer-readable instructions stored in the at least one memory, wherein the at least one processor is configured to perform operations comprising:
obtaining input data including characteristic data of a curved corner part of a training curved cover glass and characteristic data of a flat corner part of a training preform cover glass;
generating cover glass characteristic data based on the input data;
training a machine learning model to generate a predicted design specification of a target preform cover glass based on the cover glass characteristic data;
obtaining characteristic data of a curved corner part of a target curved cover glass, and
generating, using the trained machine learning model, a predicted design specification for a preform cover glass corresponding to the target curved cover glass based on the cover glass characteristic data.

19. The computer device of claim 18, wherein the at least one processor is further configured to perform operations comprising:
obtaining training input data corresponding to the curved corner part of the training curved cover glass and training output data corresponding to the flat corner part of the training preform cover glass corresponding to the training curved cover glass;
generating transformed curvature data based on the training input data and the training output data, wherein the transformed curvature data include the characteristic data of the training curved cover glass and the characteristic data of the training preform cover glass;
generating augmented training data based on the training input data and the training output data and the transformed curvature data; and
generating the predicted design specification of a target preform cover glass.

20. The computer device of claim 19, wherein:
the curved corner part of the training curved cover glass is segmented into a plurality of surfaces, wherein each of the plurality of surfaces includes one or more characteristic curves.
